(19) United States
(12) Patent Application Publication
(10) Pub. No.: US 2024/0002719 A1
(43) Pub. Date: Jan. 4, 2024

(54) PHOSPHOR PARTICLES AND LIGHT-EMITTING DEVICE

(71) Applicant: DENKA COMPANY LIMITED, Tokyo (JP)

(72) Inventors: Shunsuke MITANI, Tokyo (JP); Keita KOBAYASHI, Tokyo (JP)

(73) Assignee: DENKA COMPANY LIMITED, Tokyo (JP)

(21) Appl. No.: 18/039,684

(22) PCT Filed: Nov. 4, 2021
(86) PCT No.: PCT/JP2021/040524

§ 371 Date: May 31, 2023

(30) Foreign Application Priority Data
Dec. 4, 2020 (JP) 2020-201666

(51) Int. Cl. C09K 11/64; C09K 11/59; C09K 11/55; C09K 11/08; H01L 33/50

(52) U.S. Cl. CPC C09K 11/64; C09K 11/59; C09K 11/55; C09K 11/0883; H01L 33/50; C09K 2211/10

(57) ABSTRACT

Phosphor particles are composed of one or two selected from a powdery phosphor formed of CASN and SCASN, wherein a particle size corresponding to a cumulative 50% is Dx50 and to a cumulative 90% is Dx90 in a volume-based integrated fraction of the phosphor particles, and where a particle size corresponding to a cumulative 50% is Dy50 and to a cumulative 90% is Dy90 after subjecting the particles to treatment, (a) Dx50 is between 0.5 μm and 35 μm, and (b) Dx90/Dy90 is between 0.7 and 15. The treatment; a dispersion liquid wherein 30 mg of the particles are uniformly dispersed in an aqueous solution of sodium hexametaphosphate having a concentration of 0.2% and put into a cylindrical container A vibrator part of an ultrasonic homogenizer is inserted and the liquid is irradiated with ultrasonic waves at a frequency of 19.5 kHz and an output of 150 W for 3 minutes.

### TECHNICAL FIELD

The present invention relates to phosphor particles and a light-emitting device. More specifically, the present invention relates to phosphor particles for a micro LED or a mini LED and a light-emitting device.

### BACKGROUND ART

Research and development of a micro LED which is much smaller than conventional LEDs have been progressed. A micro LED display has been known as a new display using such a micro LED (for example, Patent Document 1).

In addition, the micro LED display is fundamentally different from conventional “LED backlight liquid crystal televisions” in that it is a self-luminous type which does not use a liquid crystal shutter or a polarizing plate. The structure is simple, light extraction efficiency is high in principle, and there are very few restrictions on a viewing angle.

### RELATED DOCUMENT

### Patent Document

Patent Document 1: Japanese Unexamined Patent Publication No. 2020-122846

### SUMMARY OF THE INVENTION

### Technical Problem

In recent years, expectations for miniaturization and high performance of the micro LED have been increased more and more.

However, as a particle size of phosphor particles is smaller, the phosphor particles are more easily aggregated, and as a result, there has been a tendency to cause problems such as an increase in transmittance of excitation light at a light conversion layer containing the phosphor and occurrence of nozzle clogging during formation of the light conversion layer. Therefore, there is room for improvement in terms of maintaining performance of the phosphor particles and suppressing the aggregation of the particles while reducing the particle size.

The present invention has been made in view of such circumstances. One object of the present invention is to provide phosphor particles capable of suppressing aggregation of particles while maintaining performance of the phosphor particles and reducing a particle size.

### Solution to Problem

As a result of intensive studies to achieve the above-described object, the present inventors have found that it is effective to index a variation in particle size of the phosphor particles by a predetermined ultrasonic homogenizer treatment. As a result of further studies, it has been found that, by controlling particle sizes of the phosphor particles before and after the predetermined ultrasonic homogenizer treatment, more specifically, by controlling both a particle size corresponding to a cumulative 50% obtained by a laser diffraction scattering method and a particle size corresponding to a cumulative 90% obtained by the laser diffraction scattering method, it is possible to obtain a phosphor which maintains its performance by while reducing the particle size and suppressing the aggregation of the particles, and the present invention has been completed.

That is, the present inventors have completed the invention provided below, thereby achieving the above-described object.

[1] Phosphor Particles Containing:
one or two selected from a powdery phosphor formed of CASN and a powdery phosphor formed of SCASN,
in which, in a case where a particle size of the phosphor particles corresponding to a cumulative 50% is denoted as Dx50 and a particle size of the phosphor particles corresponding to a cumulative 90% is denoted as Dx90 in a volume-based integrated fraction of the phosphor particles according to a laser diffraction scattering method, and
in a case where a particle size of the phosphor particles corresponding to a cumulative 50% is denoted as Dy50 and a particle size of the phosphor particles corresponding to a cumulative 90% is denoted as Dy90 after subjecting the phosphor particles to the following treatment,
(a) Dx50 is 0.5 μm or more and 35 μm or less, and
(b) Dx90/Dy90 is 0.7 or more and 15 or less.

The treatment; a dispersion liquid in which 30 mg of the phosphor particles are uniformly dispersed in 100 ml of an aqueous solution of sodium hexametaphosphate having a concentration of 0.2% is prepared, and the dispersion liquid is put into a cylindrical container having an inner diameter of 5.5 cm at a bottom. Next, a vibrator (a cylindrical chip having an outer diameter of 20 mm) part of an ultrasonic homogenizer is inserted from above the dispersion liquid, and while the vibrator is immersed to a depth of 1.0 cm or more, the dispersion liquid is irradiated with ultrasonic waves at a frequency of 19.5 kHz and an output of 150 W for 3 minutes.

[2] The phosphor particles according to [1],
in which (c) Dx50/Dy50 is 0.8 or more and 10 or less.

[3] The phosphor particles according to [1] or [2],
in which (d) (Dx90−Dx50)/(Dx50) is 0.1 or more and 25 or less.

[4] The phosphor particles according to any one of [1] to [3],
in which, in a case where a particle size of the phosphor particles corresponding to a cumulative 10% in the volume-based integrated fraction of the phosphor particles according to the laser diffraction scattering method is denoted as Dx10,
(e) (Dx90−Dx10)/(Dx50) is 0.1 or more and 25 or less.

[5] The phosphor particles according to any one of [1] to [4],
in which a specific surface area of the phosphor particles is 1.0 m²/g or more and 10 m²/g or less.

[6] The phosphor particles according to any one of [1] to [5],
in which the phosphor particles are for a micro LED or a mini LED.

[7] The phosphor particles according to [6],
in which (a′) Dx50 is 0.5 μm or more and 10 μm or less.

[8] A light-emitting device including:
a light-emitting element which emits excitation light; and
the phosphor particles according to any one of [1] to [7].

### Advantageous Effects of Invention

According to the present invention, it is possible to provide phosphor particles in which occurrence of aggregation is suppressed and performance is maintained while reducing a particle size.

### BRIEF DESCRIPTION OF THE DRAWINGS

FIG. 1 is a schematic diagram of a light-emitting device using phosphor particles according to the present embodiment.

### DESCRIPTION OF EMBODIMENTS

Hereinafter, embodiments of the present invention will be described in detail with reference to the drawings.

In all drawings, the same components are designated by the same reference numerals, and description thereof will not be repeated.

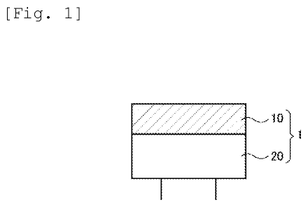

In order to avoid complication, (i) in a case where there are a plurality of the same components in the same drawing, only one of them may be given a reference numeral and not all of them, and (ii) in particular, FIG. 2 onward, the same components as those in FIG. 1 may not be denoted by reference numerals.

All drawings are for illustration purposes only. The shape and dimensional ratio of each member in the drawings do not necessarily correspond to the actual article.

In the present specification, the notation “X to Y” in the description of numerical range means X or more and Y or less, unless otherwise specified. For example, “1% to 5% by mass” means “1% by mass or more and 5% by mass or less”.

In the present specification, “LED” stands for Light Emitting Diode.

<Phosphor Particles>

In the present embodiment, the term “phosphor particles” does not intend one powdery phosphor (one grain) individually, but a particulate phosphor composed of a plurality of powdery phosphors and a group of powdery phosphors.

In addition, in the present embodiment, the “particle size” intends a value obtained by analyzing the phosphor particles, that is, a powdery phosphor group by a laser diffraction scattering method.

The phosphor particles according to the present embodiment are phosphor particles composed of one or two selected from a powdery phosphor formed of CASN and a powdery phosphor formed of SCASN, in which, in a case where a particle size of the phosphor particles corresponding to a cumulative 50% is denoted as Dx50 and a particle size of the phosphor particles corresponding to a cumulative 90% is denoted as Dx90 in a volume-based integrated fraction of the phosphor particles according to a laser diffraction scattering method, and in a case where a particle size of the phosphor particles corresponding to a cumulative 50% is denoted as Dy50 and a particle size of the phosphor particles corresponding to a cumulative 90% is denoted as Dy90 after subjecting the phosphor particles to the following treatment, the following conditions (a) and (b) are satisfied.
(a) Dx50 is 0.5 μm or more and 35 μm or less.
(b) Dx90/Dy90 is 0.7 or more and 15 or less.

Treatment; a dispersion liquid in which 30 mg of the phosphor particles are uniformly dispersed in 100 ml of an aqueous solution of sodium hexametaphosphate having a concentration of 0.2% is put into a cylindrical container having an inner diameter of 5.5 cm at a bottom. Next, a vibrator (a cylindrical chip having an outer diameter of 20 mm) part of an ultrasonic homogenizer is inserted from above the dispersion liquid, and while the vibrator is immersed to a depth of 1.0 cm or more, the dispersion liquid is irradiated with ultrasonic waves at a frequency of 19.5 kHz and an output of 150 W for 3 minutes.

The above-described ultrasonic homogenizer treatment is a treatment for changing an aggregated state to a dispersed state in a case where the phosphor particles are aggregated. In addition, the aggregation intends to mean a state in which powdery phosphors or fine powders of the powdery phosphors are bonded together by intermolecular forces, and such bonds can be loosened by physical force as described in the treatment.

Since the phosphor particles according to the present embodiment satisfy the conditions (a) and (b), it is possible to obtain phosphor particles in which occurrence of the aggregation in the phosphor particles is suppressed and the performance is maintained while reducing an average particle size of the particle group. Although the details of the reason for this are not clear, first, by setting Dx50 of the phosphor particles to be within the range of 0.5 μm or more and 35 μm or less, it is considered that the particle size of the phosphor particles is reduced as much as possible while reducing ultrafine particles which cause the aggregation, and light emission performance is easily maintained. Furthermore, by controlling a ratio (Dx90/Dy90) of D90 of the phosphor particles before and after the specific ultrasonic homogenizer treatment, it is considered that the degree of aggregation in the phosphor particles can be controlled to a higher degree. That is, usually, in a case where phosphor particles which have been aggregated are subjected to the ultrasonic homogenizer treatment, the aggregated state can be eliminated to be the dispersed state. In the present embodiment, while specifying the treatment conditions, by setting Dx90/Dy90 to 0.7 or more, the particle size of the phosphor particles can be reduced, and by setting Dx90/Dy90 to 15 or less, the aggregation in the phosphor particles can be effectively reduced. In particular, by controlling the particle size corresponding to the cumulative 90%, aggregation property of particles with a large particle size is suppressed, so that a more significant aggregation suppressing effect can be obtained.

In the above (a), from the viewpoint of improving light emission characteristics, Dx50 is preferably 0.8 μm or more, more preferably 1.5 μm or more, and still more preferably 2.0 μm or more. On the other hand, from the viewpoint of realizing a smaller particle size while maintaining the light emission characteristics, Dx is preferably 25 μm or less, more preferably 15 μm or less, and still more preferably 10 μm or less.

In addition, in the above (b), from the viewpoint of maintaining a balance between light emission characteristics and fine particle size, Dx90/Dy90 is preferably 0.8 or more and more preferably 1.0 or more. On the other hand, from the viewpoint of improving the light emission characteristics and realizing a smaller particle size, Dx90/Dy90 is preferably 12 or less, more preferably 10 or less, and still more preferably 8.5 or less.

It is preferable that the phosphor particles according to the present embodiment further satisfy the condition (c).
(c) Dx50/Dy50 is 0.8 or more and 10 or less.

By controlling the particle size corresponding to the cumulative 50%, the aggregation property of the phosphor particles is more uniformly suppressed, so that the aggregation suppressing effect can be obtained more stably.

From the viewpoint of maintaining a balance between light emission characteristics and fine particle size, the Dx50/Dy50 is preferably 0.9 or more. On the other hand, from the viewpoint of improving the light emission characteristics and realizing a smaller particle size, Dx50/Dy50 is preferably 7 or less, more preferably 5 or less, and still more preferably 2.5 or less.

It is preferable that the phosphor particles according to the present embodiment further satisfy the condition (d).
(d) (Dx90−Dx50)/(Dx50) is 0.1 or more and 25 or less.

That is, the particle size can be reduced while suppressing the aggregation by reducing particles with a large particle size in a particle size distribution of the phosphor particles.

From the viewpoint of maintaining a balance between light emission characteristics and fine particle size, the (Dx90−Dx50)/(Dx50) is preferably 0.5 or more. On the other hand, from the viewpoint of improving the light emission characteristics and realizing a smaller particle size, (Dx90−Dx50)/(Dx50) is preferably 20 or less, more preferably 10 or less, and still more preferably 4.0 or less.

It is preferable that the phosphor particles according to the present embodiment further satisfy the condition (e).

In a case where a particle size of the phosphor particles corresponding to a cumulative 10% in the volume-based integrated fraction of the phosphor particles according to the laser diffraction scattering method is denoted as Dx10,
(e) (Dx90−Dx10)/(Dx50) is 0.1 or more and 25 or less.

That is, broadening of the particle size distribution of the phosphor particles is suppressed, and phosphor particles having a more uniform particle size can be obtained.

From the viewpoint of maintaining a balance between light emission characteristics and fine particle size, the (Dx90−Dx10)/(Dx50) is preferably 0.5 or more and more preferably 1.0 or more. On the other hand, from the viewpoint of improving the light emission characteristics and realizing a smaller particle size, (Dx90−Dx10)/(Dx50) is preferably 20 or less, more preferably 10 or less, and still more preferably 4.0 or less.

In the present embodiment, the measurement by the laser diffraction scattering method is performed using, for example, “LS13-320” manufactured by Beckman Coulter, Inc. In addition, the volume-based integrated fraction represents a cumulative passing fraction (integrated passing fraction) from a small particle size side.

A specific surface area of the phosphor particles is preferably 1.0 m²/g or more and 10 m²/g or less, and more preferably 1.5 m²/g or more and 7 m²/g or less.

As a result, the aggregation in the phosphor particles can be suppressed more stably.

In order to obtain the phosphor particles according to the present embodiment, it is important to appropriately select raw materials for the phosphor particles and to select an appropriate producing method and producing conditions.

Details of the producing conditions will be described later, and examples thereof include adjusting conditions such as crushing and pulverizing time and pulverizing speed of a granular or lumpy fired product obtained by firing the raw materials, and performing classification or decantation with the fired product after pulverizing under suitable conditions.

Hereinafter, the phosphor particles according to the present embodiment will be further described.

[General Formula and Composition of CASN and SCASN]

The phosphor particles according to the present embodiment are composed of at least one of a powdery phosphor formed of CASN or a powdery phosphor formed of SCASN.

In general, CASN has the same crystal structure as CaAlSiN₃ in a main crystal phase, and refers to a phosphor represented by a general formula of MAlSiN₃:Eu (M is one or more elements selected from Sr, Mg, Ca, and Ba). Among these, a Sr-containing phosphor which has the same crystal structure as CaAlSiN₃ in the main crystal phase and is represented by a general formula of (Sr,Ca)AlSiN₃:Eu is called SCASN. CASN or SCASN works as a red-emitting phosphor, mainly because a part of Ca²⁺ of CaAlSiN₃ is replaced with Eu²⁺ acting as a light emission center.

Whether or not the main crystal phase of the produced CASN or SCASN has the same crystal structure as the CaAlSiN₃ crystal can be confirmed by a powder X-ray diffraction.

The phosphor particles according to the present embodiment do not exclude CASN and SCASN containing unavoidable elements or impurities. However, from the viewpoint of good light emission characteristics and visibility improvement of a display, it is preferable to have as few unavoidable elements and impurities as possible.

An oxygen content of the phosphor particles according to the present embodiment is preferably 1% by mass or more, and more preferably 1% by mass or more and 5% by mass or less.

The CASN and SCASN phosphors may react with moisture and be deteriorated. In order to prevent the deterioration, it is preferable to form an oxide film on a surface of the particles. As a result of oxide film formation, the oxygen content can be the values mentioned above. Incidentally, since the specific surface area increases as the particle diameter decreases, an area of the oxide film on the surface of the particles tends to increase and the oxygen amount tends to increase. The oxide film is usually formed by an acid treatment step described later.

[Light Emission Characteristics]

With regard to the phosphor particles according to the present embodiment, a light absorptance for light having a wavelength of 700 nm is preferably 20% or less, more preferably 15% or less, and still more preferably 10% or less. Realistically, the lower limit of the light absorptance for light having a wavelength of 700 nm is 1%.

The light having a wavelength of 700 nm is one of light having a wavelength that Eu, which is an activating element of the phosphor, does not originally absorb. By evaluating the degree of absorptance of light having a wavelength of 700 nm, it is possible to confirm the degree of excess light absorption due to defects in the phosphor. By producing phosphor particles having a low light absorptance for light having a wavelength of 700 nm, it is possible to obtain phosphor particles preferred for use in displays.

With regard to the phosphor particles according to the present embodiment, a light absorptance at 455 nm is preferably 75% or more and 99% or less, and more preferably 80% or more and 96% or less. By setting the light absorptance at 455 nm to be within the numerical range, light from a blue LED is not unnecessarily transmitted, so that the phosphor particles according to the present embodiment are preferred for use in a micro LED display or a mini LED.

With regard to the phosphor particles according to the present embodiment, an internal quantum efficiency is preferably 50% or more, more preferably 60% or more, still more preferably 65% or more, and even more preferably 70% or more. By setting the internal quantum efficiency to 50% or more, the light from the blue LED is moderately absorbed, and sufficient red light is emitted. The upper limit of the internal quantum efficiency is not particularly limited, but for example, 90%.

With regard to the phosphor particles according to the present embodiment, an external quantum efficiency is preferably 35% or more, more preferably 50% or more, still more preferably 60% or more, and even more preferably 65% or more. By setting the external quantum efficiency to 35% or more, the light from the blue LED is moderately absorbed, and sufficient red light is emitted. The upper limit of the external quantum efficiency is not particularly limited, but for example, 86% or less.

[Use]

The phosphor particles according to the present embodiment are for a micro LED or a mini LED. In other words, the phosphor particles according to the present embodiment are used for converting color of light emitted from the micro LED or the mini LED into another color.

In a case where the phosphor particles according to the present embodiment are for a micro LED or a mini LED, it is preferable to satisfy the following condition (a′).

(a′) Dx50 is 0.5 μm or more and 10 μm or less.

From the viewpoint of LED miniaturization, the upper limit of DX50 is preferably as small as possible, preferably 9 μm or less and more preferably 8 μm or less.

As a result, it is possible to stably obtain the light emission characteristics suitable for the micro LED or the mini LED.

The phosphor particles according to the present embodiment are composed of one or two selected from a powdery phosphor formed of CASN and a powdery phosphor formed of SCASN. As a result, the phosphor particles according to the present embodiment normally convert blue light into red light.

<Method for Producing Phosphor Particles>

In a method for producing the phosphor particles according to the present embodiment satisfying the above-described conditions (a) to (e), it is suitable to select appropriate raw materials and select appropriate producing method and producing conditions.

It is suitable that the method for producing the phosphor particles according to the present embodiment includes the following steps.
Mixing step of mixing starting raw materials to form a raw material mixed powder
Firing step of firing the raw material mixed powder obtained in the mixing step to obtain a fired product
Low-temperature firing step (annealing step) performed after the fired product obtained in the firing step is once powdered
Pulverizing step of pulverizing the low-temperature fired powder obtained after the low-temperature firing step into fine powder
Decantation step of removing fine powder generated in the pulverizing step
Step of filtering and drying the obtained sediment
Acid treatment step of removing impurities which are considered to be derived from the firing step

In the present embodiment, the “step” includes not only an independent step, but also a step which cannot be clearly distinguished from other steps as long as the intended purpose of the step is achieved.

As the findings of the present inventors, the phosphor particles according to the present embodiment are obtained according to a producing method different from conventional producing methods of CASN and SCASN, by newly combining known techniques such as (i) performing the pulverizing step under appropriate conditions using a ball mill and (ii) performing the decantation step appropriately.

Each of the above-described steps will be described below.
Mixing step

In the mixing step, the starting raw materials are mixed to form a raw material mixed powder.

Examples of the starting raw materials include europium compounds, strontium compounds such as strontium nitride, calcium compounds such as calcium nitride, silicon nitrides such as α-type silicon nitride, and aluminum nitride.

The form of each of the above-described starting raw materials is preferably powder.

Examples of the europium compound include an oxide containing europium, a hydroxide containing europium, a nitride containing europium, an oxynitride containing europium, and a halide containing europium. These can be used alone or in combination of two or more. Among these, it is preferable to use europium oxide, europium nitride, or europium fluoride alone, and it is more preferable to use europium oxide alone.

In the firing step described later, the europium is divided into solid-solution, volatilization, and remaining as a heterogeneous component. The heterogeneous component containing the europium can be removed by the acid treatment or the like. However, in a case where the heterogeneous component is produced in an excessive amount, an insoluble component is produced by the acid treatment, resulting in a decrease in brightness. In addition, in a case where the heterophase does not absorb excess light, it may remain in a state of remaining, and the europium may be contained in this heterophase.

In the mixing step, the raw material mixed powder can be obtained by, for example, a method of dry-mixing the starting raw materials, a method of wet-mixing each of the starting raw materials with an inert solvent which does not substantially react with the starting raw materials, and then removing the solvent. As a mixing device, for example, a small mill mixer, a V-type mixer, a rocking mixer, a ball mill, a vibration mill, or the like can be used. The raw material mixed powder can be obtained by, after mixing using the device, removing aggregates with a sieve as necessary.

In order to suppress deterioration of the starting raw materials and unintentional mixing of oxygen, it is preferable that the mixing step is carried out under a nitrogen atmosphere with as little moisture (humidity) as possible.
Firing step

In the firing step, the raw material mixed powder obtained in the mixing step is fired to obtain a fired product.

A firing temperature in the firing step is not particularly limited, but is preferably 1800° C. or higher and 2100° C. or lower, and more preferably 1900° C. or higher and 2000° C. or lower.

In a case where the firing temperature is equal to or higher than the above-described lower limit value, grain growth of the phosphor particles proceeds more effectively. Therefore, it is possible to further improve the light absorptance, the internal quantum efficiency, and the external quantum efficiency.

In a case where the firing temperature is equal to or lower than the above-described upper limit value, decomposition of the phosphor particles can be further suppressed. Therefore, it is possible to further improve the light absorptance, the internal quantum efficiency, and the external quantum efficiency.

Other conditions such as heating time, heating rate, heating and holding time, and pressure in the firing step are not particularly limited, and may be appropriately adjusted according to the raw materials to be used. Typically, the heating and holding time is preferably 3 hours or more and 30 hours or less, and the pressure is preferably 0.6 MPa or more and 10 MPa or less. From the viewpoint of controlling the oxygen concentration, it is preferable that the firing step is carried out under a nitrogen gas atmosphere. That is, it is preferable that the firing step is carried out under a nitrogen gas atmosphere with a pressure of 0.6 MPa or more and 10 MPa or less.

In the firing step, as a method of firing the mixture, for example, a method of filling the mixture in a container made of a material (such as tungsten) which does not react with the mixture during firing, and heating the mixture under a nitrogen atmosphere can be adopted.

The fired product obtained through the firing step is usually a granular or lumpy fired body. By using treatments such as crushing, pulverizing, and classification alone or in combination, the fired product can be powdered once.

Examples of a specific treatment method include a method of pulverizing the fired body to a predetermined particle size using a general pulverizer such as a ball mill, a vibration mill, and a jet mill. However, it should be noted that excessive pulverization may produce fine particles which easily scatter light, or may cause crystal defects on the surface of the particles, thereby causing a decrease in light emission efficiency.
Low-temperature firing step (annealing step)

After the firing step, a low-temperature firing step (annealing step) of heating the fired product (preferably, the fired product powdered once) at a temperature lower than the firing temperature in the firing step to obtain a low-temperature fired powder may be included.

It is preferable that the low-temperature firing step (annealing step) is carried out under an atmosphere of an inert gas such as noble gas and nitrogen gas, or a reducing gas such as hydrogen gas, carbon monoxide gas, hydrocarbon gas, and ammonia gas, a mixed gas thereof, or under a non-oxidizing atmosphere other than pure nitrogen, such as vacuum. It is particularly preferable to be carried out under a hydrogen gas atmosphere or an argon atmosphere.

The low-temperature firing step (annealing step) may be carried out under atmospheric pressure or under pressure. A heat treatment temperature in the low-temperature firing step (annealing step) is not particularly limited, but is preferably 1200° C. or higher and 1700° C. or lower, and more preferably 1300° C. or higher and 1600° C. or lower. A time for the low-temperature firing step (annealing step) is not particularly limited, but is preferably 3 hours or more and 12 hours or less, and more preferably 5 hours or more and 10 hours or less.

By carrying out the low-temperature firing step (annealing step), the light emission efficiency of the phosphor particles can be sufficiently improved. In addition, rearrangement of the elements removes distortions or defects, so that transparency can also be improved. In the low-temperature firing step (annealing step), the heterophase may occur. However, this can be sufficiently removed by the steps described below.
Pulverizing step

In the pulverizing step, the powder obtained in the low-temperature firing step (annealing step) is pulverized into fine powder.

It is particularly preferable that the pulverizing step is carried out with the powder after the acid treatment step by a ball mill. By carrying out the pulverization at a rotation speed which is neither too fast nor too slow for a time which is neither too long nor too short, the particle size can be reduced while maintaining the performance of the phosphor particles.

Among these, the pulverization by a ball mill is preferably carried out by a wet process using ion-exchanged water with zirconia balls. Details are not clear, but by using water and zirconia balls, it is presumed that properties of the surface of the powder to be treated are appropriately adjusted and modified.
Decantation step

In the decantation step, first, the phosphor particles pulverized through the pulverizing step are put into an appropriate dispersion medium to disperse the phosphor particles in the dispersion medium.

As the dispersion medium, for example, sodium hexametaphosphate, sodium pyrophosphate (Napp), trisodium phosphate (TSP), lower alcohol, acetone, an aqueous solution containing a surfactant, or the like can be used. A weight ratio of the phosphor particles to the dispersion medium in this case is preferably 2% or more and 40% or less, more preferably 3% or more and 20% or less, and still more preferably 4% or more and 10% or less. As the dispersion treatment in the dispersion medium, it is preferable to carry out a dispersion treatment using ultrasonic waves. Accordingly, fine particles can be removed with high accuracy and efficiency. As a result, fine particles which cause the aggregation can be reduced, which makes it easier to suppress the aggregation.

Next, after carrying out the dispersion treatment, the dispersion medium containing the phosphor particles is allowed to stand under predetermined conditions, or subjected to centrifugal separation under predetermined conditions to settle the particles.

Various conditions during particle settlement are calculated using the Stokes expression.

$${v}_{s} = \frac{{D}_{p}^{2} ( {ρ}_{p} - {ρ}_{f} ) g}{18 η} \qquad [ Expression 1 ]$$

vs: terminal velocity; [m/s] or [cm/s]
Dp: particle diameter; [m] or [cm]
ρp: density of particles; [kg/m³] or [g/cm³]
ρf: density of fluid; [kg/m³] or [g/cm³]
g: gravitational acceleration; [m/s²] or [cm/s²]
η: viscosity of fluid; [Pa·s] or [g/(cm·s)]

In the case of the stationary state, first, a settlement distance is arbitrarily determined, and then the particle diameter of the fine particles to be removed is determined. A settlement rate is calculated by substituting the particle diameter, the gravitational acceleration of 1G, and various values into the Stokes expression. A stationary time is calculated from the obtained settlement rate and the settlement distance determined arbitrarily.

In the case of the centrifugal separation, first, the settlement distance and the settlement time are arbitrarily determined, and then the settlement rate is obtained from these values. Next, a particle diameter of the fine particles to be removed is determined. The gravitational acceleration is calculated by substituting the particle diameter, the settlement rate, and various values (values specific to the solvent and particles) into the Stokes expression. A rotation speed of the centrifugal separator is obtained using the relational expression between a rotation speed specific to the centrifugal separator and the gravitational acceleration.

Subsequently, after the particles are allowed to settle, a supernatant liquid is removed. As a result, it is possible to remove the fine particles (ultrafine powder) which are contained in the supernatant liquid and may adversely affect optical properties. In addition, the aggregation due to the ultrafine powder is reduced.

Examples of a particle size of the fine particles (ultrafine powder) include a particle size having D50 of less than 0.4 μm.

Such decantation operations may be carried out repeatedly. In the present embodiment, it is preferable to repeat the decantation operation 2 times or more and 10 times or less, and more preferable to repeat the decantation operation 3 times or more and 7 times or less.
Filtration and drying step

After completion of the decantation step, the obtained sediment is filtered and dried, and as necessary, coarse particles are removed using a sieve. As a result, the fine particles (ultrafine powder) are reduced, and the phosphor particles according to the present embodiment can be obtained.
Acid treatment step

In the acid treatment step, the phosphor particles obtained in the decantation step, in which the fine particles (ultrafine powder) are reduced, are acid-treated. As a result, at least a part of impurities which do not contribute to the light emission can be removed. Incidentally, it is presumed that the impurities which do not contribute to the light emission are generated during the firing step or the low-temperature firing step (annealing step).

As the acid, an aqueous solution containing one or more acids selected from hydrofluoric acid, sulfuric acid, phosphoric acid, hydrochloric acid, and nitric acid can be used. Hydrofluoric acid, nitric acid, or a mixed acid of hydrofluoric acid and nitric acid is particularly preferable.

The acid treatment can be carried out by dispersing the low-temperature fired powder in the aqueous solution containing the above-described acid. A stirring time is, for example, 10 minutes or more and 6 hours or less, preferably 30 minutes or more and 3 hours or less. A temperature during the stirring can be, for example, 40° C. or higher and 90° C. or lower, preferably 50° C. or higher and 70° C. or lower.

After the acid treatment step, it is desirable to separate substances other than the phosphor particles by filtration, and to wash the substances adhering to the phosphor particles with water.

Through the series of steps described above, the phosphor particles according to the present embodiment can be obtained.

<Light-Emitting Device and Self-Luminous Display>

FIG. 1 is a schematic diagram of a light-emitting device 1.

The light-emitting device 1 includes a light-emitting element 20 and the above-described phosphor particles. In addition, a complex 10 may be provided in contact with an upper portion of the light-emitting element 20.

The light-emitting element 20 emits excitation light and is typically a blue LED. A terminal exists below the light-emitting element 20. The light-emitting element 20 can emit light by connecting the terminal to a power supply.

The excitation light emitted from the light-emitting element 20 may be wavelength-converted by the complex 10. In a case where the excitation light is blue light, the blue light is wavelength-converted to red light by the complex 10 containing CASN and/or SCASN.

The complex 10 may be constituted of the above-described phosphor particles and a sealing material which seals the phosphor particles.

Various curable resins can be used as the sealing material. Any curable resin can be used as long as it is sufficiently transparent and provides optical properties required for the display.

Examples of the sealing material include a silicone resin. In addition to a silicone resin OE-6630 manufactured by Dow Corning Toray Co., Ltd. and silicone materials manufactured by Shin-Etsu Chemical Co., Ltd. described above, various silicone resins (for example, those sold as silicone for LED lighting) can be used. The silicone resin is preferable from the viewpoint of heat resistance as well as transparency.

An amount of the phosphor particles in the complex 10 is, for example, 10% by mass or more and 70% by mass or less, preferably 25% by mass or more and 55% by mass or less.

The size and shape of the light-emitting element 20 are not particularly limited as long as they correspond to the micro LED or the mini LED and are applicable to micro LED displays or mini LED displays.

By using the light-emitting device 1 as a pixel (typically, a red pixel), a self-luminous display (micro LED display or mini LED display) can be configured. By using a combination of the light-emitting device 1 (micro LED or mini LED) emitting red light, a micro LED or a mini LED emitting blue light, and micro LED or a mini LED emitting green light, a self-luminous display (micro LED display or mini LED display) capable of color display can be configured.

Incidentally, as the micro LED or the mini LED emitting blue light, for example, LED in which the complex 10 is excluded in the light-emitting device 1 of FIG. 1 (that is, only blue LED) can be used. In addition, as the micro LED or the mini LED emitting green light, for example, LED in which the complex 10 in the light-emitting device 1 of FIG. 1 contains β-sialon rather than CASN and/or SCASN-based phosphors can be used.

The embodiments of the present invention have been described above, but these are examples of the present invention and various configurations other than the above can be adopted. In addition, the present invention is not limited to the above-described embodiments, and modifications, improvements, and the like within the range in which the object of the present invention can be achieved are included in the present invention.

### EXAMPLES

Embodiments of the present invention will be described in detail based on Examples and Comparative Examples. It should be noted that the present invention is not limited to Examples only.

### Example 1

Phosphor particles composed of a powdery phosphor formed of SCASN were produced by the following procedure.

1) Mixing Step

The following materials were mixed in a glove box maintained in a nitrogen atmosphere with a moisture content of 1 mass ppm or less and an oxygen content of 1 mass ppm or less.
α-type silicon nitride powder (Si₃N₄, SN-E10 grade, manufactured by UBE Industries Ltd.) 25.65% by mass
Calcium nitride powder (Ca₃N₂, manufactured by TAIHEIYO CEMENT CORPORATION) 2.98% by mass
Aluminum nitride powder (AlN, E grade, manufactured by Tokuyama Corporation) 22.49% by mass
Strontium nitride powder (Sr₂N, manufactured by Materion Corporation) 43.09% by mass
Europium oxide powder (Eu₂O₃, manufactured by NIPPON YTTRIUM CO., LTD.) 5.79% by mass

Incidentally, a nitrogen content was determined when the raw materials were blended according to the above-described molar ratio.

The mixing was carried out using a small mill mixer to achieve sufficient dispersion and mixing.

After completion of the mixing, the mixture was passed through a sieve with an opening of 150 μm to remove aggregates, and the resultant was used as a raw material mixed powder. The raw material mixed powder was filled in a lidded container made of tungsten.

2) Firing Step

The container filled with the raw material mixed powder was taken out from the glove box, quickly set in an electric furnace equipped with a carbon heater, and the inside of the furnace was sufficiently evacuated to 0.1 Pa or less.

Heating was started while the evacuation was continued, and after reaching 850° C., nitrogen gas was introduced into the furnace to keep the atmospheric pressure in the furnace constant at 0.8 MPaG.

The heating was continued to 1950° C. even after the introduction of nitrogen gas was started. Firing was carried out at the firing and holding temperature (1950° C.) for 4 hours, and then the heating was stopped and the container was cooled. After cooling to room temperature, a red mass collected from the container was crushed with a mortar. Thereafter, a powder (fired product) was finally obtained by passing the red mass through a sieve with an opening of 250 μm.

3) Low-Temperature Firing Step (Annealing Step)

The fired product obtained in the firing step was filled in a cylindrical boron nitride container, and the container was placed in an electric furnace equipped with a carbon heater. By holding at 1350° C. for 8 hours in an argon flow atmosphere at atmospheric pressure, a low-temperature fired powder was obtained.

4) Pulverizing Step

The low-temperature fired powder obtained in the low-temperature firing step was put into a mixed liquid of water and ethanol to form a dispersion liquid. The dispersion liquid was subjected to a ball mill pulverization using a ball mill (zirconia balls). Table 1 shows the rotation speed (rpm) and time (h) of the ball mill pulverization. As a result, a pulverized powder was obtained.

5) Decantation Step

First, the phosphor particles pulverized through the pulverizing step were put into a dispersion medium to disperse the phosphor particles in the dispersion medium. Ultrasonic waves were used for the dispersion (Table 1). As the dispersion medium, an aqueous solution of ion-exchanged water containing 0.05% by mass of sodium hexametaphosphate was used in which a weight ratio was adjusted as shown in Table 1.

Subsequently, a decantation step was carried out to remove fine powder from a supernatant liquid in which the pulverized powder of the phosphor particles was settled in the dispersion medium. In the decantation operation, a settlement time of the phosphor particles was calculated according to the Stokes expression under a setting that particles having a diameter of 2 μm or less could be removed, and then a supernatant liquid above a predetermined height was removed at the same time that a predetermined time had elapsed from the start of settlement. For the removal, a device was used in which the supernatant liquid was removed by sucking up the upper liquid from a pipe having an inlet at a predetermined height of the cylindrical container.

The decantation operation was repeated (Table 1).

6) Filtration and Drying Step

The sediment obtained in the decantation step was filtered, dried, and passed through a sieve with an opening of 75 μm. Coarse particles which did not pass through the sieve were removed.

7) Acid Treatment Step

An acid treatment was carried out to remove impurities which may be formed during the firing.

Specifically, the powder passed through the sieve as described above was immersed in 0.5 M hydrochloric acid such that the powder concentration was 26.7% by mass, and then subjected to an acid treatment by stirring the mixture for 1 hour while heating. Thereafter, the powder was separated from the hydrochloric acid solution by filtration at room temperature of approximately 25° C., and washed with pure water. Thereafter, the powder washed with pure water was dried in a dryer at 100° C. or higher and 120° C. or lower for 12 hours. The dried powder was classified with a sieve having an opening of 75 μm.

By the above-described procedure, phosphor particles of Example 1 were obtained.

### Examples 2 to 6 and Comparative Examples 1 to 3

Phosphor particles were obtained in the same manner as in Example 1, except that the pulverizing step was carried out under the conditions shown in Table 1 and the decantation step was carried out.

The following measurements and evaluations were performed using each of the obtained phosphor particles. The results are shown in Table 2.

<Confirmation of Crystal Structure>

With regard to each of the phosphor particles of Examples and Comparative Examples, using an X-ray diffractometer (Ultima IV manufactured by Rigaku Corporation), a crystal structure thereof was confirmed by a powder X-ray diffraction pattern using Cu-Kα rays.

It was confirmed that the powder X-ray diffraction pattern of each of the phosphor particles of Examples and Comparative Examples was the same as a diffraction pattern of CaAlSiN₃ crystal. That is, it was confirmed that, in Examples and Comparative Examples, SCASN-based phosphors having the same crystal structure as CaAlSiN₃ in the main crystal phase were obtained.

<Measurement of Particle Diameter>

1) Using Microtrac MT3300EXII (MicrotracBEL Corp.) which is a particle diameter measuring device using a laser diffraction and scattering method, a particle size distribution of the phosphor particles before the following treatment was measured. From the obtained particle size distribution, particle sizes Dx10, Dx50, and Dx90 corresponding to cumulative 10%, 50%, and 90% in the volume-based integrated fraction were obtained, respectively.

2) Next, with the phosphor particles subjected to the following treatment, a particle size distribution was measured in the same manner as in 1), and from the obtained particle size distribution, particle sizes Dy10, Dy50, and Dy90 corresponding to cumulative 10%, 50%, and 90% in the volume-based integrated fraction were obtained, respectively.

As the ultrasonic homogenizer, “US-150E” (manufactured by NIHONSEIKI KAISHA LTD.) was used.

(Treatment) A dispersion liquid in which 30 mg of each of the phosphor particles were uniformly dispersed in 100 ml of an aqueous solution of sodium hexametaphosphate having a concentration of 0.2% is prepared, and the dispersion liquid was put into a cylindrical container having an inner diameter of 5.5 cm at a bottom. Next, a vibrator (a cylindrical chip having an outer diameter of 20 mm) part of an ultrasonic homogenizer was inserted from above the dispersion liquid, and while the vibrator was immersed to a depth of 1.0 cm or more, the dispersion liquid was irradiated with ultrasonic waves at a frequency of 19.5 kHz and an output of 150 W for 3 minutes.

<Specific Surface Area>

Approximately 0.25 g of each of the obtained phosphor particles was degassed under reduced pressure at 300° C. for approximately 5 hours, and then a krypton gas adsorption isotherm was measured at liquid nitrogen temperature (77 K) (measurement device: BELSORP-max manufactured by MicrotracBEL Corp.) and a specific surface area was obtained by a BET method.

<Light Emission Characteristics>

With regard to each of the phosphor particles of Examples and Comparative Examples, light absorptance at 455 nm, internal quantum efficiency, and external quantum efficiency were calculated by the following procedure.

The phosphor particles were packed into a concave cell with a smooth surface and attached to an opening of an integrating sphere. As excitation light for the phosphor, a monochromatic light having a wavelength of 455 nm, separated from a light emission source (Xe lamp), was introduced into the integrating sphere using an optical fiber. The phosphor sample was irradiated with the monochromatic light, and a fluorescence spectrum of the sample was measured using a spectrophotometer (MCPD-7000 manufactured by OTSUKA ELECTRONICS CO., LTD.).

From the spectral data obtained, the number of excited and reflected light photons (Qref) and the number of fluorescence photons (Qem) were calculated. The number of excited and reflected light photons was calculated in the same wavelength range as the number of excitation light photons, and the number of fluorescence photons was calculated in a range of 465 to 800 nm.

In addition, using the same apparatus, a standard reflector (Spectralon (registered trademark) manufactured by Labsphere, Inc.) with a reflectance of 99% was attached to the opening of the integrating sphere, and a spectrum of excitation light having a wavelength of 455 nm was measured. In this case, the number of excitation light photons (Qex) was calculated from the spectrum in a wavelength range of 450 to 465 nm.

The light absorptance at 455 nm and the internal quantum efficiency of each of the phosphor particles of Examples and Comparative Examples were obtained by the following expressions.

Light absorptance at 455 nm (%)={(Qex−Qref)/Qex}×100

Internal quantum efficiency (%)={(Qem/(Qex−Qref)}×100

On the other hand, the external quantum efficiency was obtained by the following expression.

External quantum efficiency (%)=(Qem/Qex)×100

Therefore, with respect to the above-described expressions, the external quantum efficiency had the following relationship.

External quantum efficiency=Light absorptance at 455 nm×Internal quantum efficiency

A peak wavelength of the phosphor particles of Examples and Comparative Examples was determined by a wavelength showing the highest intensity in the wavelength range of 465 nm to 800 nm in the spectral data obtained by attaching the phosphor to the opening of the integrating sphere.

Tables 1 and 2 collectively show the production conditions (including raw material composition) and evaluation results for each of Examples and Comparative Examples.

TABLE 1

| | Treatment conditions | | | | |
|---|---|---|---|---|---|
| | | | Decantation step | | |
| | | | Weight | | |
| | | | ratio of | | |
| | | | phosphor | | |
| | Pulverizing step | | particles to | | Dispersion |
| | Rotation | | dispersion | Number of | with |
| | speed | Time | medium | repetition | ultrasonic |
| | [rpm] | [h] | [wt %] | [times] | waves |
| Comparative | 60 | 23 | None | None | N |
| Example 1 | | | | | |
| Comparative | 60 | 25 | None | None | N |
| Example 2 | | | | | |
| Comparative | 60 | 27 | None | None | N |
| Example 3 | | | | | |
| Example 1 | 60 | 0.0167 | 9% | 5 | Y |
| Example 2 | 60 | 3 | 9% | 5 | Y |
| Example 3 | 60 | 23 | 9% | 5 | Y |
| Example 4 | 60 | 27 | 9% | 5 | Y |
| Example 5 | 60 | 5 | 9% | 5 | Y |
| Example 6 | 60 | 20 | 9% | 5 | Y |

TABLE 2

| | | | | | | | | | Particle size parameter | |
|---|---|---|---|---|---|---|---|---|---|---|
| | Particle size (μm) | | | | | | | | (c) | (b) |
| | After treatment | | | | Before treatment | | | | Dx50/ | Dx90/ |
| | Dy10 | Dy50 | Dy90 | Dmax | D10x | (a) D50x | D90x | Dmax | Dy50 | Dy90 |
| Comparative | 0.3 | 0.7 | 2.0 | 10.9 | 0.5 | 2.5 | 50.6 | 244.8 | 3.57 | 25.30 |
| Example 1 | | | | | | | | | | |
| Comparative | 0.3 | 0.7 | 1.9 | 10.9 | 0.4 | 1.7 | 48.3 | 147.1 | 2.43 | 25.42 |
| Example 2 | | | | | | | | | | |
| Comparative | 0.3 | 0.7 | 1.8 | 10.9 | 0.4 | 3.2 | 57.4 | 291.5 | 4.57 | 31.89 |
| Example 3 | | | | | | | | | | |
| Example 1 | 5.0 | 7.8 | 12.5 | 36.8 | 5.2 | 7.8 | 11.9 | 26.0 | 1.00 | 0.95 |
| Example 2 | 2.4 | 5.7 | 10.7 | 36.8 | 2.7 | 5.7 | 9.9 | 21.9 | 1.00 | 0.93 |
| Example 3 | 0.4 | 1.2 | 3.6 | 21.7 | 0.5 | 1.3 | 6.6 | 72.9 | 1.08 | 1.83 |
| Example 4 | 0.4 | 1.0 | 3.6 | 73.2 | 0.5 | 1.4 | 33.9 | 173.3 | 1.40 | 9.42 |
| Example 5 | 1.7 | 4.3 | 9.6 | 30.9 | 2.1 | 4.8 | 10.6 | 36.3 | 1.12 | 1.10 |
| Example 6 | 0.6 | 1.7 | 4.1 | 18.4 | 0.7 | 1.8 | 4.3 | 18.4 | 1.06 | 1.05 |

| | Particle size parameter | | Specific | Light emission characteristics | | |
|---|---|---|---|---|---|---|
| | (d) | (e) | surface | Light | Internal | External |
| | (Dx90 − | (Dx90 − | area | absorptance | quantum | quantum |
| | Dx50)/Dx50 | Dx10)/Dx50 | (m²/g) | at 455 nm | efficiency | efficiency |
| Comparative | 19.24 | 20.04 | 6.99 | 77.6% | 62.8% | 48.8% |
| Example 1 | | | | | | |
| Comparative | 27.41 | 28.18 | 7.12 | 77.3% | 62.0% | 47.9% |
| Example 2 | | | | | | |
| Comparative | 16.94 | 17.81 | 7.7 | 75.0% | 62.8% | 47.1% |
| Example 3 | | | | | | |
| Example 1 | 0.53 | 0.86 | 1.01 | 95.1% | 70.2% | 66.8% |
| Example 2 | 0.74 | 1.26 | 1.35 | 93.6% | 69.8% | 65.4% |
| Example 3 | 4.08 | 4.69 | 3.89 | 82.0% | 68.2% | 55.9% |
| Example 4 | 23.21 | 23.86 | 6.48 | 79.9% | 64.1% | 51.2% |
| Example 5 | 1.21 | 1.77 | 1.52 | 92.7% | 72.7% | 67.4% |
| Example 6 | 1.39 | 2.00 | 3.23 | 86.4% | 71.4% | 61.7% |

Priority is claimed on Japanese Patent Application No. 2020-201666, filed Dec. 4, 2020, the disclosure of which is incorporated herein by reference.

### REFERENCE SIGNS LIST

1 light-emitting device
10 complex
20 light-emitting element

1. Phosphor particles comprising:
one or two selected from a powdery phosphor formed of CASN and a powdery phosphor formed of SCASN,
wherein, in a case where a particle size of the phosphor particles corresponding to a cumulative 50% is denoted as Dx50 and a particle size of the phosphor particles corresponding to a cumulative 90% is denoted as Dx90 in a volume-based integrated fraction of the phosphor particles according to a laser diffraction scattering method, and in a case where a particle size of the phosphor particles corresponding to a cumulative 50% is denoted as Dy50 and a particle size of the phosphor particles corresponding to a cumulative 90% is denoted as Dy90 after subjecting the phosphor particles to the following treatment, (a) Dx50 is 0.5 μm or more and 35 μm or less, and (b) Dx90/Dy90 is 0.7 or more and 15 or less,
the treatment; a dispersion liquid in which 30 mg of the phosphor particles are uniformly dispersed in 100 ml of an aqueous solution of sodium hexametaphosphate having a concentration of 0.2% is prepared, the dispersion liquid is put into a cylindrical container having an inner diameter of 5.5 cm at a bottom, a vibrator (a cylindrical chip having an outer diameter of 20 mm) part of an ultrasonic homogenizer is inserted from above the dispersion liquid, and while the vibrator is immersed to a depth of 1.0 cm or more, the dispersion liquid is irradiated with ultrasonic waves at a frequency of 19.5 kHz and an output of 150 W for 3 minutes.

2. The phosphor particles according to claim 1,
wherein (c) Dx50/Dy50 is 0.8 or more and 10 or less.

3. The phosphor particles according to claim 1,
wherein (d) (Dx90−Dx50)/(Dx50) is 0.1 or more and 25 or less.

4. The phosphor particles according to claim 1,
wherein, in a case where a particle size of the phosphor particles corresponding to a cumulative 10% in the volume-based integrated fraction of the phosphor particles according to the laser diffraction scattering method is denoted as Dx10, (e) (Dx90−Dx10)/(Dx50) is 0.1 or more and 25 or less.

5. The phosphor particles according to claim 1,
wherein a specific surface area of the phosphor particles is 1.0 m²/g or more and 10 m²/g or less.

6. The phosphor particles according to claim 1,
wherein the phosphor particles are for a micro LED or a mini LED.

7. The phosphor particles according to claim 6,
wherein (a′) Dx50 is 0.5 μm or more and 10 μm or less.

8. A light-emitting device comprising:
a light-emitting element which emits excitation light; and
the phosphor particles according to claim 1.
